(19) United States
(12) Patent Application Publication
(10) Pub. No.: US 2013/0219812 A1
(43) Pub. Date: Aug. 29, 2013

(54) SOLAR PANEL ROOF-RIDGE MOUNTING SYSTEMS AND METHODS

(71) Applicant: Georgia Tech Research Corporation, (US)

(72) Inventors: Joseph Goodman, Atlanta, GA (US); Russell Gentry, Decatur, GA (US); Bradley Wilson Brooks, Atlanta, GA (US); Tristan Farris Al-Haddad, Atlanta, GA (US)

(73) Assignee: GEORGIA TECH RESEARCH CORPORATION, Atlanta, GA (US)

(21) Appl. No.: 13/776,292

(22) Filed: Feb. 25, 2013

Related U.S. Application Data
(60) Provisional application No. 61/602,791, filed on Feb. 24, 2012.

(51) Int. Cl. H01L 31/042; E04G 21/14

(52) U.S. Cl. CPC H01L 31/0422; E04G 21/14
USPC 52/173.3; 52/745.21

(57) ABSTRACT

An exemplary embodiment of the present invention provides a solar panel roof-ridge mounting system for use in mounting one or more solar panels to a roof of a building. The system can comprise a base plate and a plurality of attachment members coupled to the base plate. The base plate can be configured to interface with a deck of the roof at a roof-ridge. The base plate can comprise a first side and an opposing second side. The first side can be configured for placement adjacent a first side of the roof-ridge, and the second side can be configured for placement adjacent an opposing second side of the roof-ridge. The attachment members can be configured to couple the roof-ridge mounting system to a support system of the one or more solar panels.

### CROSS-REFERENCE TO RELATED APPLICATIONS

This application claims the benefit of U.S. Provisional Application Ser. No. 61/602,791, filed on 24 Feb. 2012, which is incorporated herein by reference in its entirety as if fully set forth below.

### FEDERALLY SPONSORED RESEARCH STATEMENT

This invention was made with Government support under Agreement No. DE-EE0005441, awarded by the Department of Energy. The Government has certain rights in the invention.

### TECHNICAL FIELD OF THE INVENTION

The various embodiments of the present disclosure relate generally to systems and methods for mounting solar panels on roofs. More particularly, the various embodiments of the present invention are directed to systems and methods for mounting solar panels to roofs via a roof-ridge of the roofs.

### BACKGROUND OF THE INVENTION

Over the past few decades, increasing focus has been given to solar power as a possible source of clean and sustainable energy. Many residential homes, as well as commercial buildings, make use of local solar panels to provide at least a portion of the power used by the home/building. As shown in FIG. 1, conventionally, solar panels 105 are mounted to the roof 101 of a home via a plurality of connectors 110 coupled to the deck 115 of a roof 101. The connectors 110 often require multiple roof/deck penetrations by fasteners 111, such as screws, nails, bolts, etc., in order to securely couple the connectors 110 to the deck 115.

These conventional roof mounting systems 100 lead to many problems. For example, the connectors 110 require numerous roof/deck penetrations, which increases the risk of roof leaks. This problem is exacerbated by the location of the connectors 110—below the roof-ridge 102. Specifically, the amount of water passing over the connector penetrations is increased because water sheds down the roof onto the penetrations, which are located below the roof-ridge 102. Additionally, because the conventional mounting systems 100 use nonlinearly-aligned connectors 110 along the bottom of the panels 105 to connect the panels 105 to the deck 115, it is very difficult to access the roof deck 115 beneath the panels 105 after installation. To do so typically requires complete disconnection and removal of the solar panels 105 from the roof 101. Further, because conventional mounting systems 100 employ a plurality of connectors 110 positioned on a roof deck 115 without any true reference point, it is very difficult for workers installing the mounting system 100 to squarely align the solar panels 105 on the roof 101, which is often desired for aesthetical reasons. Still another disadvantage of conventional mounting systems 100 is the high amount of hardware and man-hours necessary to install those systems 100.

Accordingly, there is a desire for improved solar-panel roof mounting systems that remedy one or more of the disadvantages discussed above. Various embodiments of the present invention address this desire.

### BRIEF SUMMARY OF THE INVENTION

The present invention relates to solar panel roof-ridge mounting systems and methods. An exemplary embodiment of the present invention provides a solar panel roof-ridge mounting system for use in mounting one or more solar panels to a roof of a building. In an exemplary embodiment, the system comprises a base plate, a plurality of attachment members coupled to the base plate, and a plurality of apertures in the base plate. The base plate can be configured to interface with a deck of a roof at a roof-ridge. The base plate can comprise a first side and an opposing second side. The first side of the base plate can be configured for placement adjacent a first side of the roof-ridge. The second side of the base plate can be configured for placement adjacent an opposing second side of the roof-ridge. The plurality of attachment members can be configured to couple the roof-ridge mounting system to a solar panel support system. The plurality of apertures in the base plate can be configured for receiving a fastener for attaching the base plate to the deck of the roof.

In another exemplary embodiment, each attachment member in the plurality of attachment members comprises a first end, a second end, and at least one aperture between the first end and the second end.

In yet another exemplary embodiment, the system further comprises a connection member passing through the at least one aperture of at least two of the plurality of attachment members. In still another exemplary embodiment, the connection member is arranged substantially parallel to at least one of the first side and the second side of the base plate.

In another exemplary embodiment, at least a portion of the base plate between the first side and the second side is flexible to accommodate various pitch angles of the roof-ridge.

In yet another exemplary embodiment, the base plate comprises an alignment guide for aligning the base plate. In some embodiments, the alignment guide comprises a first alignment point on a first end of the base plate and a second alignment point on a second end of the base plate. In some embodiments, the first and second alignment points are positioned on the base plate such that when the first and second alignment points are positioned proximate an apex of the roof-ridge, the first side of the base plate is substantially parallel to the roof-ridge.

In still another exemplary embodiment, the base plate further comprises a plurality of ventilation apertures for providing fluid communication between a space beneath the deck and an ambient atmosphere above the deck.

In another exemplary embodiment, the roof-ridge mounting system further comprises a cap comprised of a hydrophobic material. The cap can be positioned substantially above the base plate to substantially prevent rain water from entering the plurality of apertures in the base plate.

In addition to solar panel roof-ridge mounting systems, the present invention also provides solar panel roof-ridge mounting methods. An exemplary embodiment of the present invention provides a method of attaching one or more solar panels to a roof. In an exemplary embodiment, the method comprises placing a roof-ridge mounting system along a roof-ridge of the roof, such that a first side of the roof-ridge mounting system is positioned substantially on a first side of the roof-ridge and an opposing second side of the roof-ridge mounting system is positioned substantially on an second side of the roof-ridge, attaching the roof-ridge mounting system to a deck of the roof, coupling the one or more solar panels to a structural member of a solar panel support system, and attaching a first end of the structural member to the roof-ridge mounting system proximate a first side of the roof-ridge mounting system.

In another exemplary embodiment, placing the roof-ridge mounting system along the roof-ridge comprises bending at least a portion of the roof-ridge mounting system between the first and second sides of the roof-ridge mounting system such that the first and second sides form an angle substantially equal to an angle formed by the first and second sides of the roof-ridge.

In yet another exemplary embodiment, attaching the roof-ridge mounting system to the deck comprises inserting one or more fasteners into the deck through one or more apertures in a base plate of the roof-ridge mounting system.

In still another exemplary embodiment, the roof-ridge mounting system comprises a plurality of attachment members positioned along the first side of the roof-ridge mounting system, and each attachment member in the plurality of attachment members comprises an aperture. In an exemplary embodiment, attaching a first end of the structural member to the roof-ridge mounting system can comprise inserting a connection member through the apertures in the plurality of connection members, and placing a hook on the first end of the structural member around at least a portion of the connection member. In another exemplary embodiment, attaching a first end of the structural member to the roof-ridge mounting system comprises aligning a plurality of apertures on the first end of the structural member with the apertures on the plurality of attachment members, and inserting a connection member through both the apertures on the first end of the structural member and the apertures on the plurality of attachment members.

In another exemplary embodiment, the method further comprises attaching a hydrophobic cap over the roof-ridge mounting system, such that the cap substantially covers penetrations in the deck of the roof used to attach the roof-ridge mounting system to the deck.

In yet another exemplary embodiment, the method further comprises coupling a harness of a user to the roof-ridge mounting system.

In still another exemplary embodiment, the method further comprises attaching a hoist to the roof-ridge mounting system, and hoisting the one or more solar panels with the hoist from a first location to a location proximate the roof-ridge mounting system.

In another exemplary embodiment, placing the roof-ridge mounting system along the roof-ridge comprises aligning a first alignment point on a base plate of the roof-ridge mounting system with roof-ridge, and aligning a second alignment point on the base plate with the roof-ridge, such that after aligning the first and second alignment points, the first side of the roof-ridge mounting system is substantially parallel to the roof-ridge.

In still another exemplary embodiment, the one or more solar panels is attached to the roof without any penetrations to the deck of the roof beneath the one or more solar panels.

In yet another exemplary embodiment, the method further comprises attaching a second end of the structural member to the roof deck.

These and other aspects of the present invention are described in the Detailed Description of the Invention below and the accompanying figures. Other aspects and features of embodiments of the present invention will become apparent to those of ordinary skill in the art upon reviewing the following description of specific, exemplary embodiments of the present invention in concert with the figures. While features of the present invention may be discussed relative to certain embodiments and figures, all embodiments of the present invention can include one or more of the features discussed herein. Further, while one or more embodiments may be discussed as having certain advantageous features, one or more of such features may also be used with the various embodiments of the invention discussed herein. In similar fashion, while exemplary embodiments may be discussed below as device, system, or method embodiments, it is to be understood that such exemplary embodiments can be implemented in various devices, systems, and methods of the present invention.

### BRIEF DESCRIPTION OF THE DRAWINGS

The following Detailed Description of the Invention is better understood when read in conjunction with the appended drawings. For the purposes of illustration, there is shown in the drawings exemplary embodiments, but the subject matter is not limited to the specific elements and instrumentalities disclosed.

FIG. 1 depicts a conventional solar panel roof mounting system.

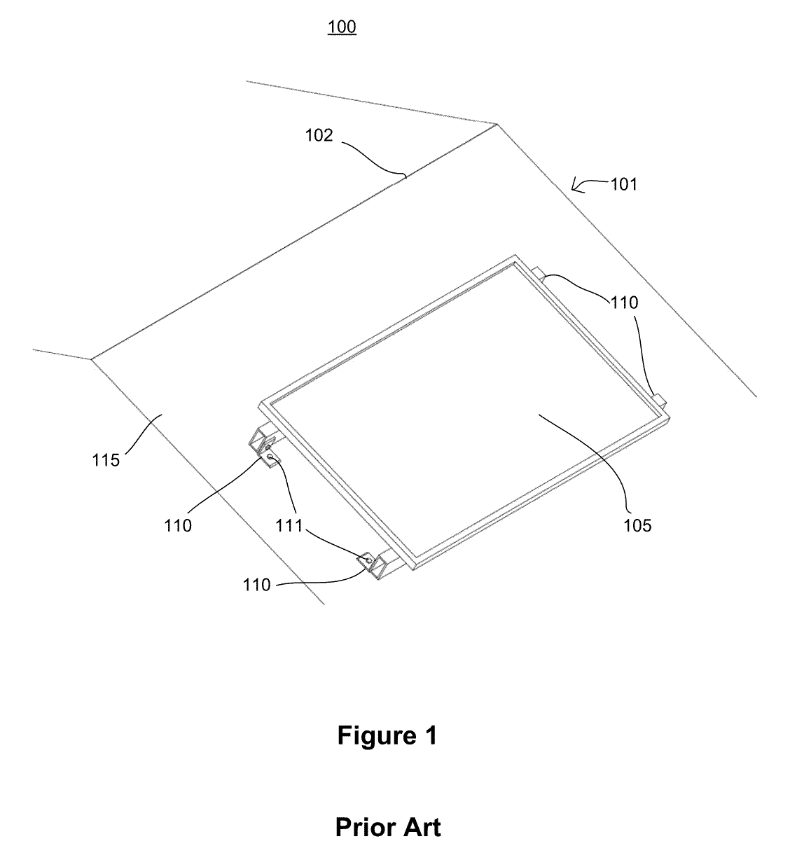

FIG. 2A depicts a solar panel roof-ridge mounting system, in accordance with an exemplary embodiment of the present invention.

FIG. 2B depicts a portion of the solar panel roof-ridge mounting system shown in FIG. 2A, in accordance with an exemplary embodiment of the present invention.

FIG. 3A depicts a solar panel roof-ridge mounting system comprising a connection member, in accordance with an exemplary embodiment of the present invention.

FIG. 3B depicts a portion of the solar panel roof-ridge mounting system shown in FIG. 3A, in accordance with an exemplary embodiment of the present invention.

FIG. 4A depicts a solar panel roof-ridge mounting system being used to mount a solar panel to a roof, in accordance with an exemplary embodiment of the present invention.

FIG. 4B depicts a portion of the solar panel roof-ridge mounting system shown in FIG. 4A, in accordance with an exemplary embodiment of the present invention.

FIG. 5A depicts a solar panel roof-ridge mounting system comprising a cap, in accordance with an exemplary embodiment of the present invention.

FIG. 5B depicts a portion of the solar panel roof-ridge mounting system shown in FIG. 5A, in accordance with an exemplary embodiment of the present invention.

FIG. 6 depicts a solar panel roof-ridge mounting system attached to multiple roof-ridges having varying roof-ridge pitch angles, in accordance with an exemplary embodiment of the present invention.

FIG. 7A depicts a solar panel roof-ridge mounting system comprising a plurality of connection members, in accordance with an exemplary embodiment of the present invention.

FIG. 7B depicts a portion of the solar panel roof-ridge mounting system shown in FIG. 7A, in accordance with an exemplary embodiment of the present invention.

FIG. 8A depicts a solar panel roof-ridge mounting system, in accordance with an exemplary embodiment of the present invention.

FIG. 8B depicts a portion of the solar panel roof-ridge mounting system shown in FIG. 8A, in accordance with an exemplary embodiment of the present invention.

### DETAILED DESCRIPTION OF THE INVENTION

To facilitate an understanding of the principles and features of the present invention, various illustrative embodiments are explained below. The components, steps, and materials described hereinafter as making up various elements of the invention are intended to be illustrative and not restrictive. Many suitable components, steps, and materials that would perform the same or similar functions as the components, steps, and materials described herein are intended to be embraced within the scope of the invention. Such other components, steps, and materials not described herein can include, but are not limited to, similar components or steps that are developed after development of the invention.

Many exemplary embodiments of the present invention relate to a solar panel roof-ridge mounting system. As used herein, the term “roof-ridge” should be generally understood to mean a local apex of a roof. Of course, those skilled in the art would understand that a roof of a building can have more than one local apex or roof-ridge, which should be encompassed by the term “roof-ridge” as used herein.

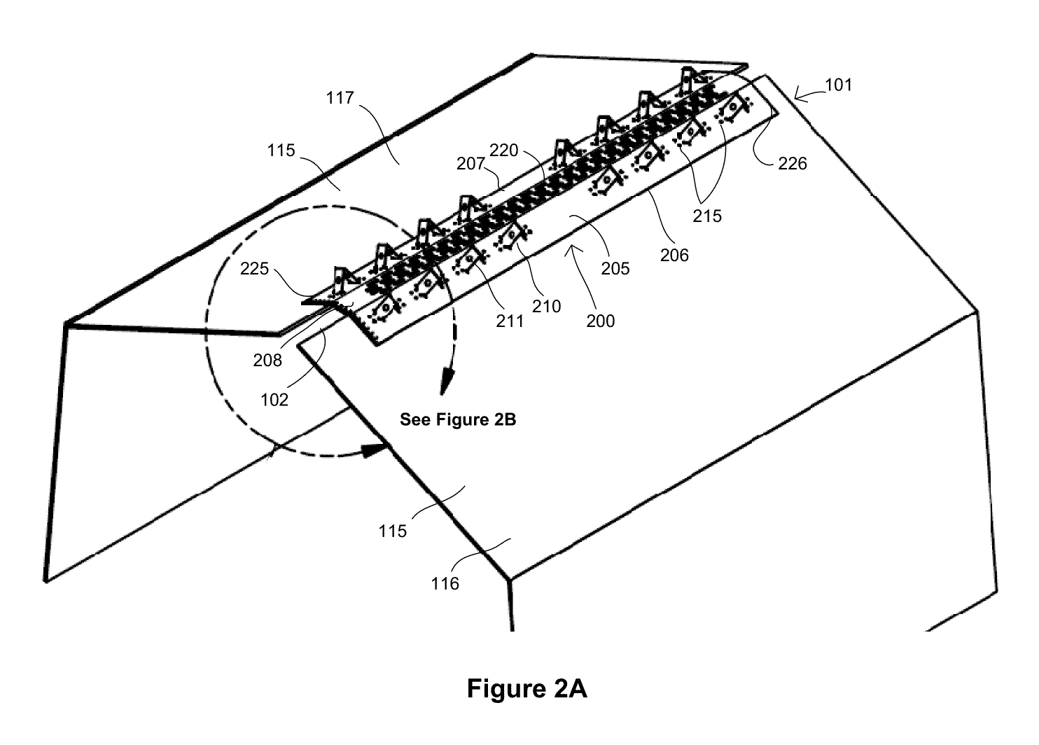

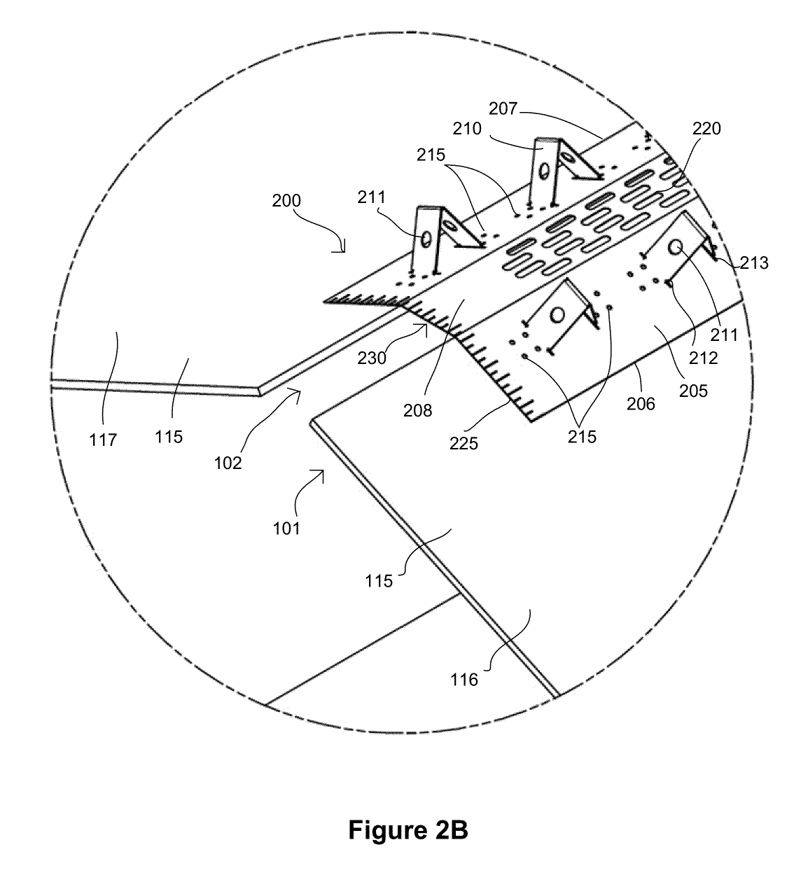

As shown in FIGS. 2A-2B, an exemplary embodiment of the present invention provides a solar panel roof-ridge mounting system 200. The system 200 can be used to mount one or more solar panels 105 to a roof 101 of a building. In an exemplary embodiment of the present invention, the system 200 comprises a base plate 205 configured to interface with the deck 115 of the roof 101 at a roof-ridge 102. The base plate 205 can comprise a first side 206 and an opposing second side 207. The first side 206 can be configured for placement adjacent a first side 116 of the roof-ridge 102, and the second side 207 can be configured for placement adjacent an opposing second side 117 of the roof-ridge 102.

The system 100 can further comprise one or more apertures 215 in the base plate 205 for receiving a fastener for attaching the base plate 205 to the deck 115 of the roof 101. Those skilled in the art would appreciate that many fasteners can be used to attach the base plate 205 to the deck 115 of the roof 101, including, but not limited to, screws, nails, bolts, and the like. The apertures 215 can have many arrangements on the base plate 205. In an exemplary embodiment, the apertures 215 can be arranged to align with rafters beneath the deck 115 of the roof 101, such that the fasteners can connect in the rafters for increased stability. In some embodiments, the apertures 215 can be positioned on the first 116 and second 117 sides of the roof-ridge 102. In some embodiments, the apertures 215 can be positioned on one of the first 116 and second 117 sides of the roof-ridge 102.

As shown in FIGS. 2A-2B, the base plate 205 can also comprise one or more ventilation apertures 220 for providing fluid communication between an area beneath the deck 115 and the ambient above the deck 115. Thus, for example, the ventilation apertures 220 can be used to ventilate the attic of a building. Those skilled in the art would appreciate the ventilation apertures 220 can have many different shapes, including, but not limited to, slots, circles, rectangles, and the like. Additionally, while the ventilation apertures 220 shown in FIGS. 2A-2B are positioned along a middle portion 208 of the base plate 205, those skilled in the art would recognize the ventilation apertures 220 could be positioned at various locations on the base plate 205 in accordance with various embodiments.

As shown in FIGS. 2A-2B, the system 200 can further comprise a plurality of attachment members 210 coupled to the base plate 205. The attachment members 210 can be configured to couple the roof-ridge mounting system 200 to a support system 106 of one or more solar panels 105. The attachment members 210 can be many different attachment members known in the art, including, but not limited to, ears, tabs, hooks, rings, notches, and the like. In an exemplary embodiment, one or more of the attachment members 210 in the plurality of attachment members comprises a first end 212, a second end 213, and at least one aperture 211 between the first end 212 and the second end 213. The attachment members 210 can be used to couple one or more solar panels 105 to the mounting system 200.

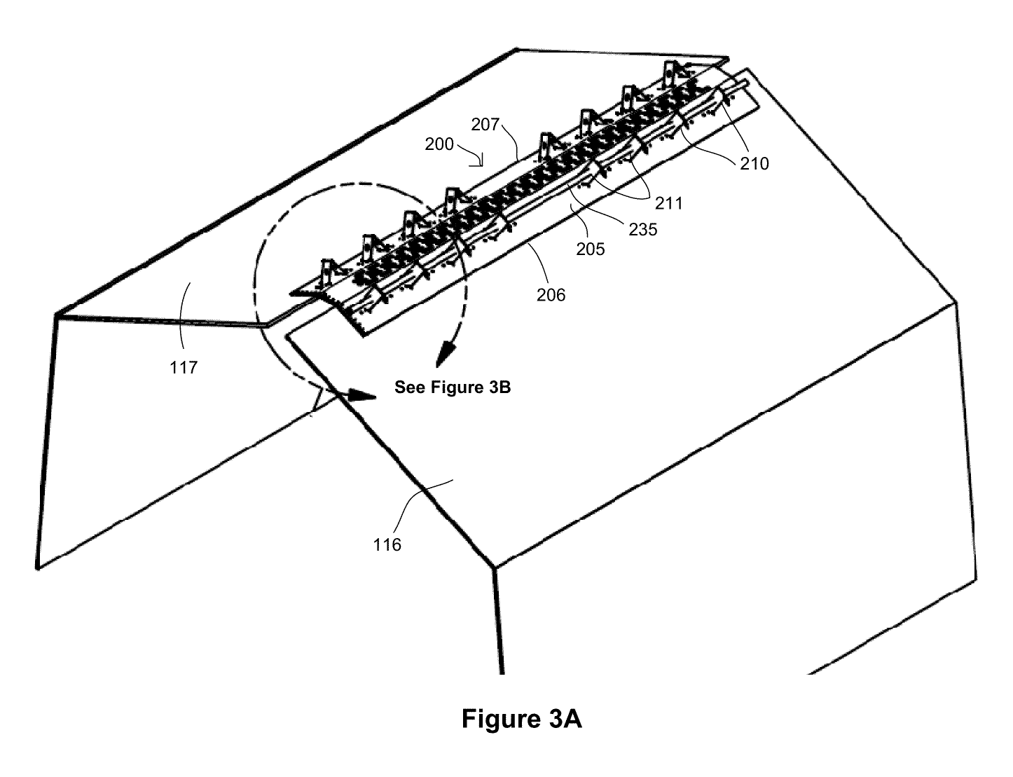

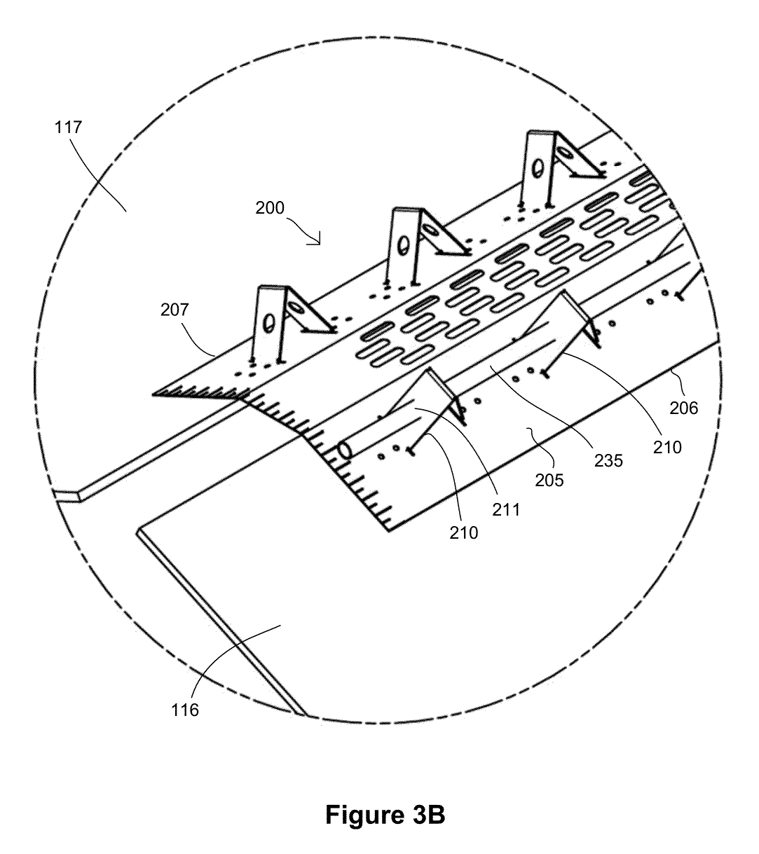

A shown in FIGS. 3A-3B, the system 200 can further comprise a connection member 235 passing through at least one aperture 211 of at least two attachment members 210. The connection member 235 can be many connection members known in the art, including, but not limited to, a rod, a conduit, a beam, and the like. The connection member 235 can also have many different cross-sectional geometric shapes, including, but not limited to circular, elliptical, polygonal, and the like. In some embodiments, the connection member 235 can pass through all apertures 211 on the attachment members 210 of a first side 206 of the base plate 205. In some embodiments, the connection member 235 is arranged substantially parallel to at least one of the first side 206 and the second side 207 of the base plate 205. In some embodiments of the present invention, the system 200 further comprises a second connection member passing through at least one aperture 211 of at least two of the attachment members 210. In some embodiments, system 200 can comprise a first connection member 235 passing through apertures 211 of attachment members 210 on a first side 206 of the base plate 205 and a second connection member passing through apertures 211 of attachment members 210 on a second side 207 of the base plate 205. In some embodiments the system 200 can comprise multiple connection members 235 passing through apertures 211 of a corresponding subset of attachment members 210 on the first 206 and/or second 207 sides of the base plate 205. For example, in some embodiments, the system 200 can comprise a first connection member 235 passing through apertures 211 of a first subset of attachment members 210 on a first side 206 of the base plate 205 and a second connection member 235 passing through apertures 211 of a second subset of attachment members 210 on the first side 206 of the base plate 205.

In some embodiments, the system 200 can comprise a connection member 235 coupled to one or more attachment members 210. Thus, in some embodiments, a first end of a connection member 235 can be coupled to a first attachment member 210, and a second end of the connection member 235 can be coupled to a second attachment member 210. The first and second ends can be coupled to the attachment members 210 many ways known in the art. For example, in some embodiments, the connection member 235 can be welded to the attachment members 210. In some embodiments, connection member 235 can comprise threaded ends that screw into opposing threaded openings in the attachment members 210.

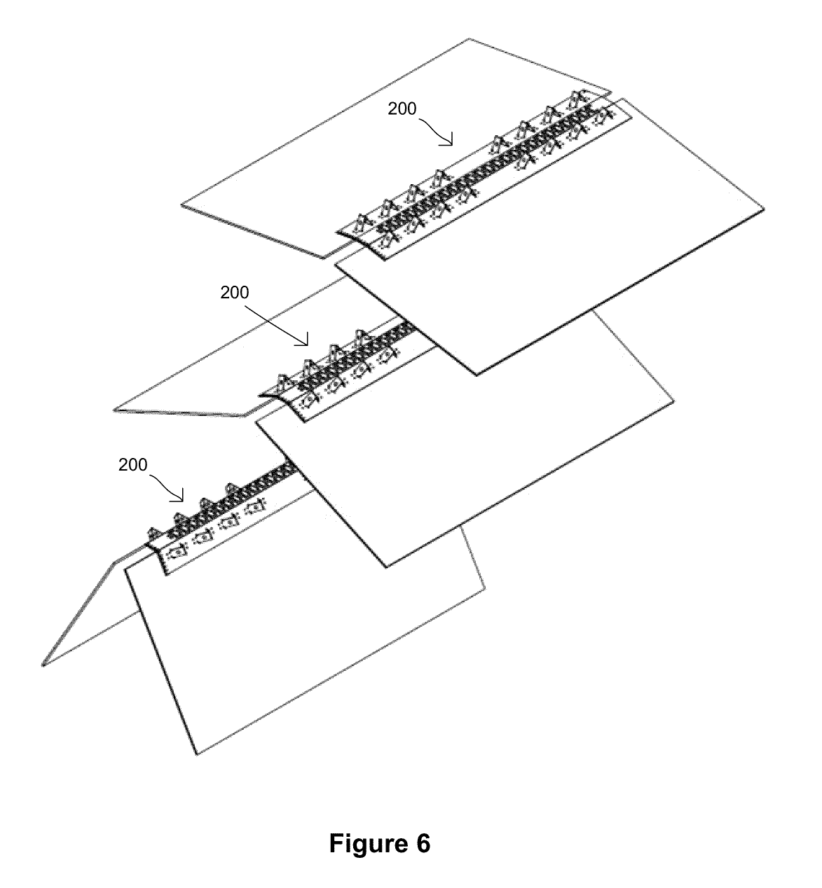

As shown in FIG. 6, in some embodiments the solar panel roof-ridge mounting systems 200 can accommodate various pitch angles of the roof-ridge 102. For purposes of illustration, the embodiments of the base plate illustrated in the figures depict the base plate as three separate portions, a portion of the first side 206, a portion on the second side 207, and a middle portion 208, with angles between the first and middle portions and between the second and middle portions. Thus, in some embodiments, one or more portions of the base plate 205 can hinge to accommodate various pitch angles of the roof-ridge 102. However, in accordance some embodiments of the present invention, at least a portion of the base plate 205 between the first side 206 and the second side 207 of the base plate 205 can be flexible, such that it can curve to the contour of the roof-ridge 102 to accommodate various pitch angles of the roof 101. The base plate 205 can comprise many different materials, including, but not limited to, steel, aluminum, iron, various metallic alloys, plastics, rubber, thermoplastics, fiber-reinforced thermosets, polymeric materials, ABS, PETG, molded fiberglass, and the like.

As discussed above, a disadvantage of many conventional mounting systems was an inability of the installer of the system to squarely align the solar panels 105 on a roof 101. This was due in part because the panels 105 were positioned on the deck 115 of the roof 101 without using any reference point on the roof 101. Accordingly, in some embodiments of the present invention, the base plate 205 can comprise an alignment guide 230 for aligning the base plate 205 about the roof-ridge 102. The alignment guide 230 can be many alignment guides known in the art. In an exemplary embodiment, the alignment guide 230 is depicted as a ruler on one or more ends of the base plate 205, such that a user can determine an accurate distance from the first 206 and/or second 207 sides of the base plate 205. The alignment guide 230 can also include one or more alignment points indicating a predetermined distance from the first 206 or second 207 sides of the base plate 205. In some embodiments, the one or more alignment points can indicate the midpoint between the first side 206 and the second side 207 of the base plate 205. For example, in an exemplary embodiment, a particular number/line on the alignment guide 230 can be the alignment point. In an exemplary embodiment, the alignment guide 230 comprises a first alignment point on a first end 225 of the base plate 205 and a second alignment point on a second end 226 of the base plate 205. The first and second alignment points can positioned on the base plate 205 such that when the first and second alignment points are positioned proximate the apex of the roof-ridge 102, the first side 206 of the base plate 205 is substantially parallel to the apex of roof-ridge 102. Accordingly, when solar panels 105 are connected to the system 200, the solar panels 105 can be substantially squared with the roof 101, leading to a more aesthetically pleasing appearance.

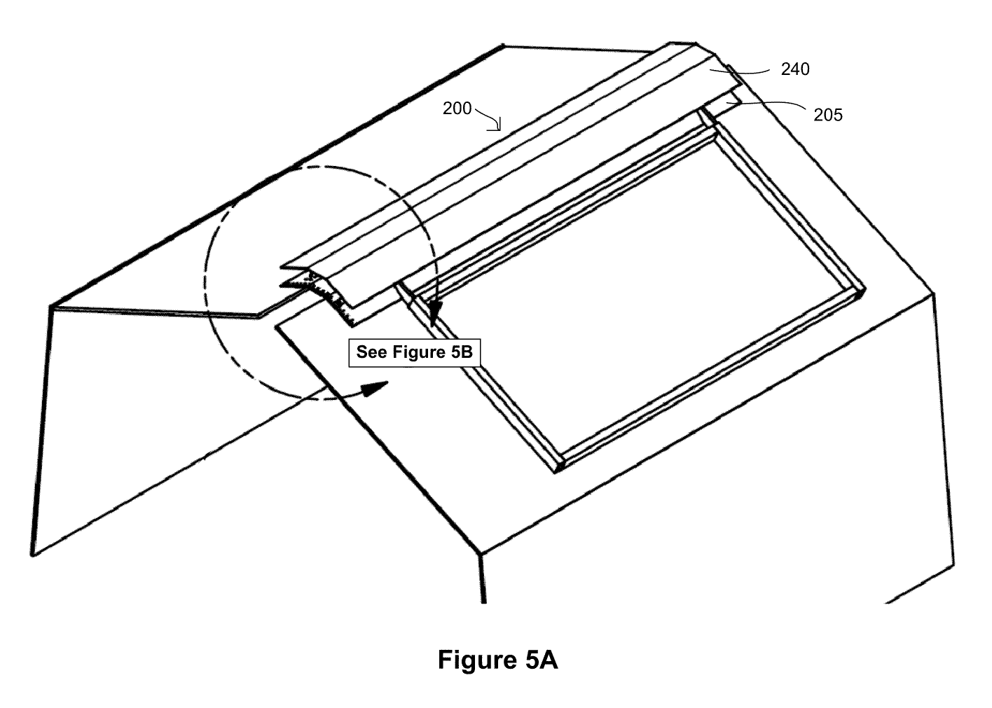

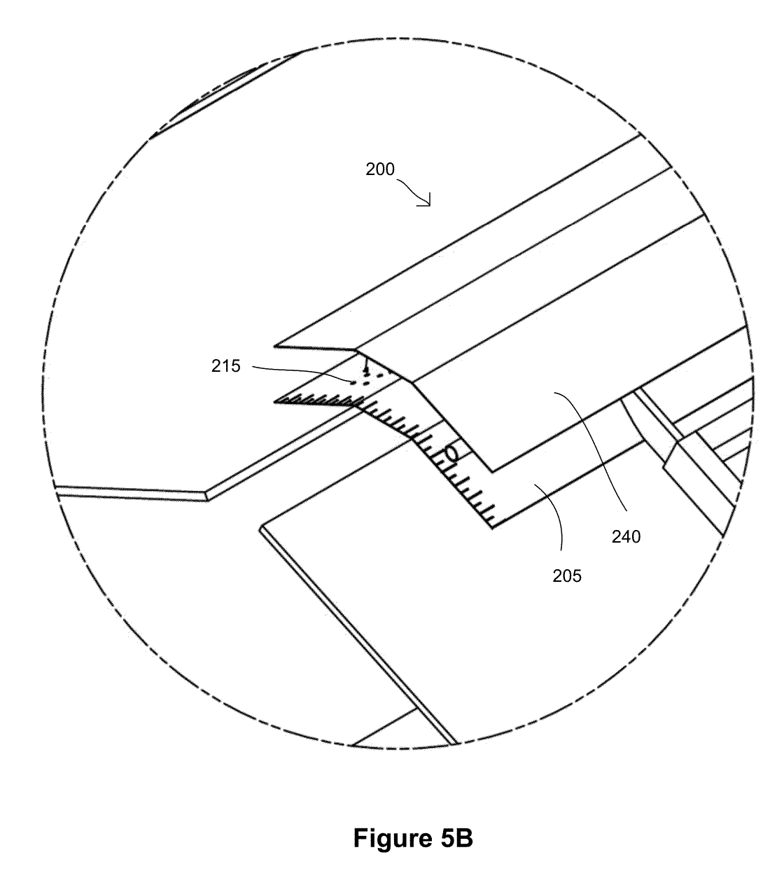

As also discussed above, another disadvantage of conventional mounting systems was a propensity for the roof penetrations used in attaching the system to the roof to cause structural water leaks. Further, this problem was exacerbated due to the position of the penetrations well below the roof-ridge 102. Various embodiments of the present invention improve upon this problem because the majority, and in some embodiments all, of penetrations to the roof deck 115 are substantially close to the roof-ridge 102, such that minimal rainwater passes over the penetrations. As shown in FIGS. 5A-5B, some embodiments of the present invention further improve this problem associated with conventional systems because the system 200 can further comprise a cap 240 positioned substantially above the base plate 205 to substantially prevent rain water from entering the plurality of apertures 215 in the base plate 205. The cap 240 can be coupled to the base plate 205 many ways known in the art. In some embodiments, at least a portion of the cap 240 is comprised of a hydrophobic material. The cap can comprise many materials known in the art, including, but not limited to, plastic, steel, aluminum, tin, metallic alloys, plastics, thermoplastics, fiber-reinforced thermosets, ABS, PET, fiber-reinforced polymeric materials, fiberglass, and the like. Additionally, to improve aesthetic appearances of the mounting system, in some embodiments, the cap 240 has substantially the same color as at least a portion of the roof 101.

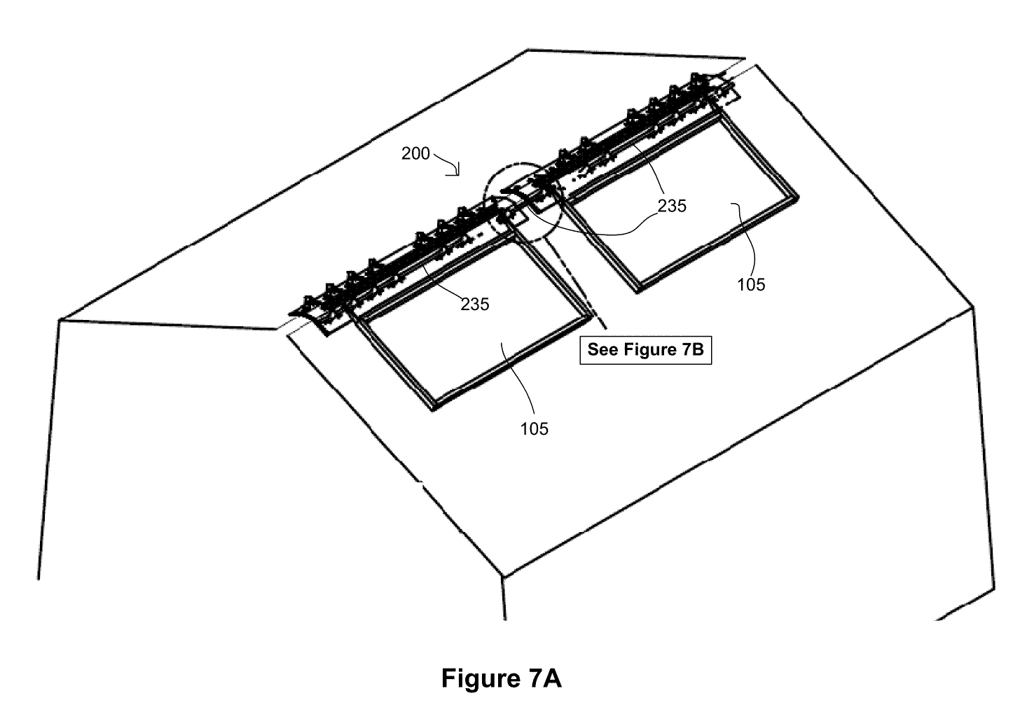

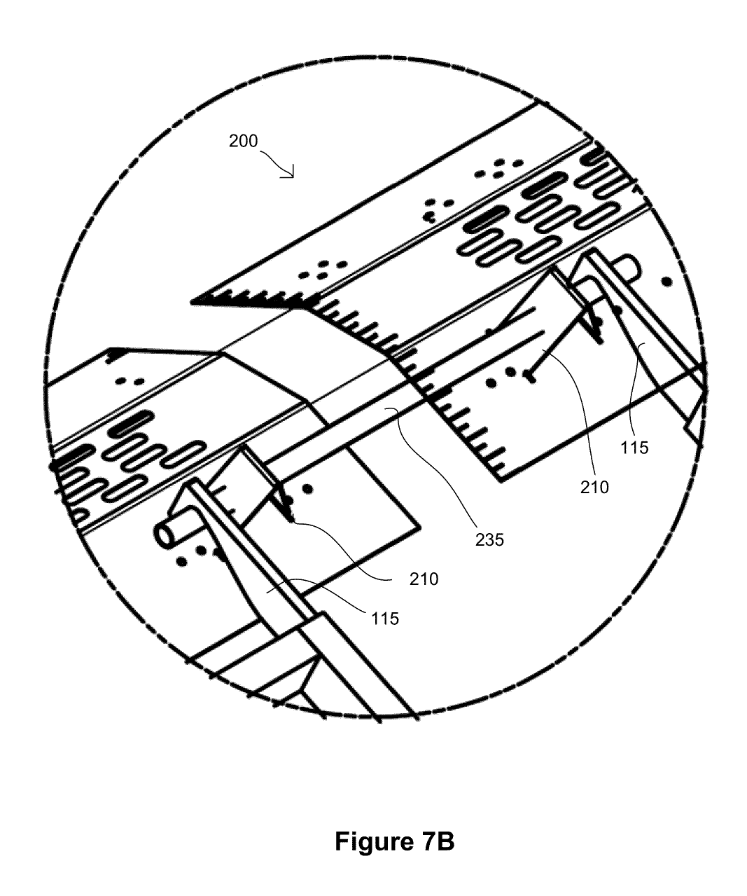

As shown in FIGS. 7A-7B, in some embodiments, a mounting system 200 can comprise multiple base plates 205 and multiple connection members 235. In some embodiments, as shown in FIGS. 7A-7B, a connection member 235 may span multiple base plates, e.g., connecting to an attachment member 210 on a first base plate and an attachment member 210 on a second base plate.

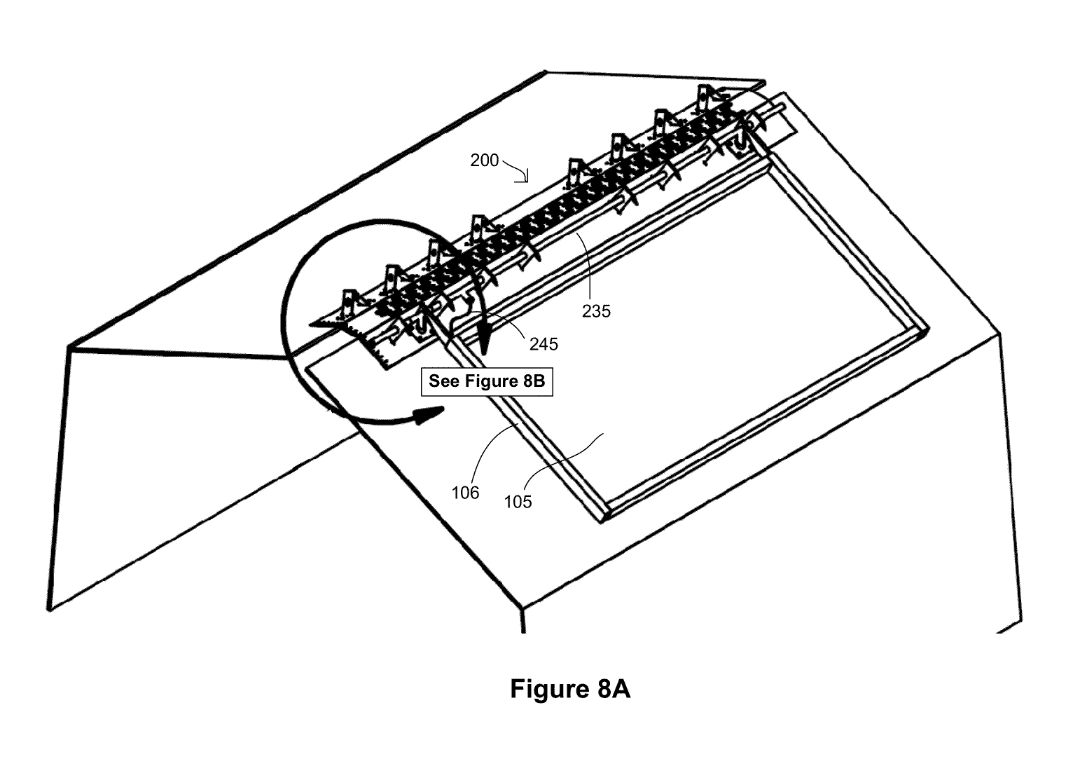

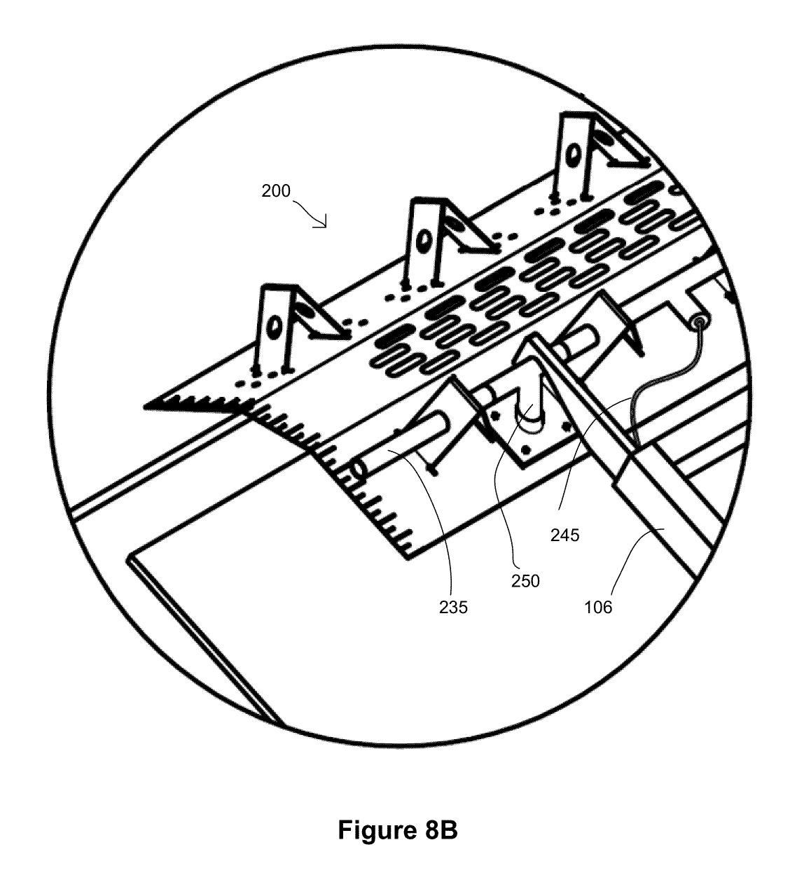

As discussed above, in some embodiments, the connection member 235 can be conduit or other structural unit having a channel within its interior. Additionally, a structural member 106 of the solar panel support system may also have a channel within its interior, which can be open or substantially closed and watertight. Accordingly, in some embodiments, the connection member 235 and/or the structural member 106 can carry a electrical conductor 245, e.g., a wire, within its channel running between the solar panel 105 and a desired location, e.g., a space beneath the roof. An exemplary embodiment with a connection member 235 and structural member 106 carrying an electrical conductor 245 is shown in FIGS. 8A-8B. As illustrated, in some embodiments, the system 200 comprises one or more connection brackets 250 providing communication between the connection member 235 and a space beneath the roof 101, e.g., the attic. The connection brackets 250 can have a channel similar to that of the connection member 235 for carrying the electrical conductor 245 from the connection member 235 into the space beneath the roof 101. In some embodiments, the connection brackets 250 can serve as attachment member 210, such that other attachment members 210 (e.g., as illustrated in FIGS. 2A-2B) are not required.

In addition to solar panel roof-ridge mounting systems, exemplary embodiments of the present invention directed towards solar panel roof-ridge mounting methods. An exemplary embodiment of the present invention provides a method of attaching one or more solar panels 105 to a roof 101. The method comprises placing a roof-ridge mounting system 200 along a roof-ridge 102 of the roof 101, attaching the roof-ridge mounting system 200 to a deck 115 of the roof 101, coupling the one or more solar panels 105 to a structural member 106 of a solar panel support system, and attaching a first end of the structural member 107 to the roof-ridge mounting system 200 proximate the first side 206 of the roof-ridge mounting system 200.

In some embodiments, placing a roof-ridge mounting system 200 along a roof-ridge 102 is performed such that the first side 206 of the roof-ridge mounting system 200 is positioned substantially on a first side 116 of the roof-ridge 102 and an opposing second side 207 of the roof-ridge mounting system 200 is positioned substantially on an second side 117 of the roof-ridge 102.

In some embodiments, placing the roof-ridge mounting system 200 along the roof-ridge 102 comprises bending at least a portion of the roof-ridge mounting system 200 between the first 206 and second 207 sides of the roof-ridge mounting system 200 such that the first 206 and second sides 207 form an angle substantially equal to an angle formed by the first 116 and second 117 sides of the roof-ridge 102. Thus, the roof-ridge mounting system 200 is capable of accommodating a wide range of roof-ridge pitch angles.

The roof-ridge mounting system 200 can be attached to the deck 115 many different ways in accordance with various embodiments of the present invention. In some embodiments, an adhesive is used to attach the mounting system 200 to the deck 115. In some embodiments, attaching the roof-ridge mounting system 200 to the deck 115 comprises inserting one or more fasteners into the deck 115 through one or more apertures 215 in a base plate 205 of the roof-ridge mounting system 200. As discussed above, the fasteners can be many fasteners known in the art. In some embodiments, the fasteners are inserted into rafters of the roof 101 through one or more apertures 215 in the base plate 205, increasing stability of the system 200.

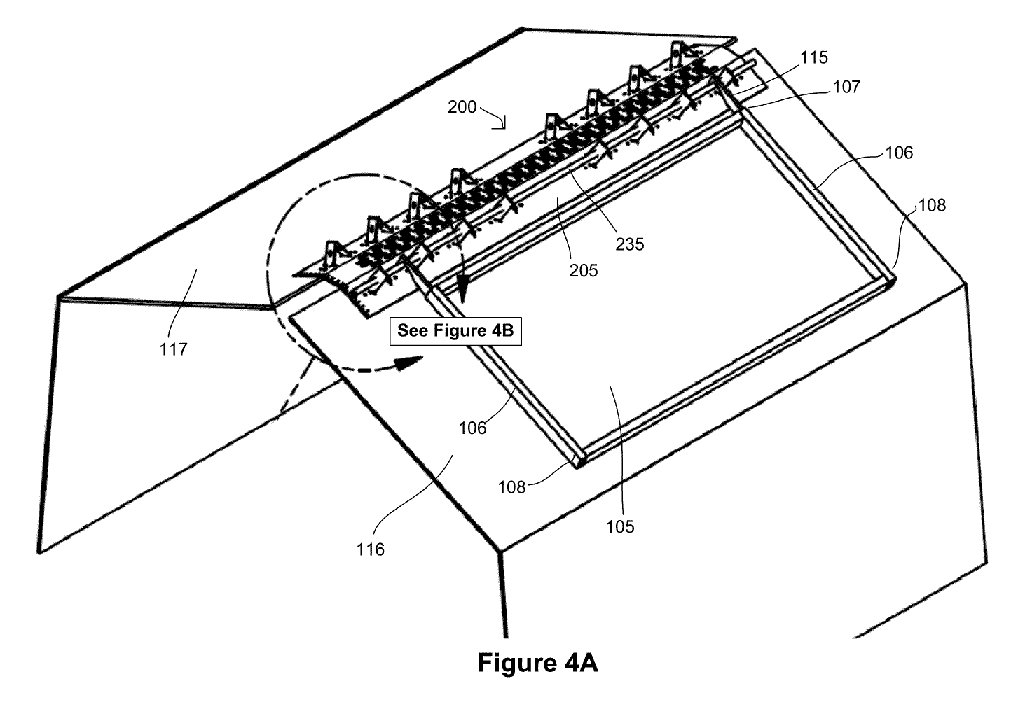

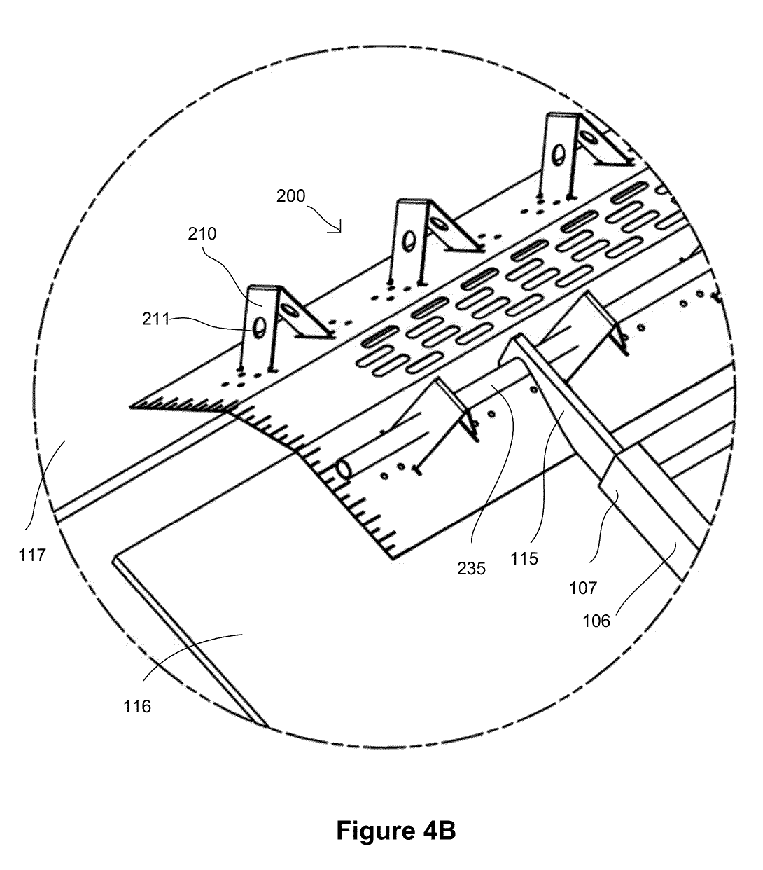

The first end 107 of the structural member 106 can also be attached or coupled to the mounting system 200 many different ways in accordance with various embodiments of the present invention. For example, as depicted in FIGS. 4A-4B and 7A-7B, in some embodiments of the present invention, attaching a first end 107 of the structural member 106 to the roof-ridge mounting system 200 comprises inserting a connection member 235 through the apertures 211 in the plurality of attachment members 210, and placing a hook 115 on the first end 107 of the structural member 106 around at least a portion of the connection member 235. In some embodiments, attaching a first end 107 of the structural member 106 to the roof-ridge mounting system 200 comprises aligning a plurality of apertures (not shown) on the first end 107 of the structural member 108 with the apertures 211 on the plurality of attachment members 210 of the mounting system 200, and inserting a connection member 235 through both the apertures (not shown) on the first end 107 of the structural member 106 and the apertures 211 on the plurality of attachment members 210. Although not shown in the figures, in some embodiments, the first end 107 of the structural member 106 can also be attached or coupled to the mounting system 200 via different types of fasteners known in the art, including, but not limited to, bolts, screws, nails, clevis-type fasteners, and the like.

As discussed above, a problem with conventional solar panel mounting systems was their propensity to cause water leaks in through the roof of a building. Accordingly, in some embodiments, the method further comprises attaching a hydrophobic cap 240 over the roof-ridge mounting system 200. In some embodiments, the cap 240 can substantially cover some or all of the penetrations in the deck 115 of the roof 101 used to attach the roof-ridge mounting system 200 to the deck 115. Therefore, the cap 240 can substantially prevent rain water from passing over the roof penetrations, thus decreasing the possibility of roof leaks. As also discussed above, this is further enhanced by the position of the mounting system 200 over the roof-ridge 102, as opposed to below the roof-ridge 102 as in conventional mounting systems 100. Additionally, in some embodiments, the one or more solar panels 105 are attached to the roof 101 without any penetrations to the deck 115 of the roof 101 beneath the one or more solar panels 105. In some embodiments, all penetrations used to attach the one or more solar panels 105 to the roof 101 are proximate the roof-ridge 102, further preventing roof leaks.

As also discussed above, a disadvantage of conventional mounting systems was an inability of installers of the system to squarely align the solar panels 105 on the roof 101. Accordingly, some embodiments of the present invention ensure that, once connected to the mounting system 200, the solar panels 105 are squarely aligned with the roof 101. For example, in some embodiments of the present invention, placing the roof-ridge mounting system 200 along the roof-ridge 102 comprises aligning a first alignment point on a base plate 205 of the roof-ridge mounting system 200 with roof-ridge 102, and aligning a second alignment point on the base plate 205 with the roof-ridge 102, such that after aligning the first and second alignment points, the first side 206 of the roof-ridge mounting system 200 is substantially parallel to the roof-ridge 102. Accordingly, when a solar panel support system, and accompanying solar panels 105, are attached to the mounting system 200, the edge of the solar panels proximate the roof-ridge 102 are substantially parallel to the roof-ridge 102, thus creating a more aesthetically desirable appearance.

Many safety standards often require workers on the roof of a building to wear a harness coupled to a point on the roof, preventing the worker from falling off of the roof. Accordingly, in some embodiments, the mounting system 200 comprises an attachment point for a harness. In some embodiments, the harness can be attached to an attachment member 210 of the mounting system 200. In some embodiments, the harness can be attached to a connection member 235 of the mounting system 200. Further, in some embodiments, the method comprises coupling a harness of a user to the roof-ridge mounting system 200.

The present invention can also make it easier for installers of the solar panel system 200 to get solar panels onto the roof for installation. For example, once the mounting system 200 has been attached to the roof ridge 102, a hoist can be attached to the roof-ridge mounting system 200 and one or more of the solar panels 105, or other equipment, can be hoisted from a first location, e.g., a truck, the ground, etc., to a location proximate the roof-ridge mounting system 200. The hoist can be many hoists known in the art, including, but not limited to, a pulley system, a wench, a ratchet-lever hoist (come-along), and the like.

As shown in FIGS. 4A-5B and 7A-7B, when the solar panels are mounted on the roof, they can be substantially coplanar with the deck 115 of the roof 101. In some embodiments, the panels 105 are pivotably coupled to the roof-ridge mounting system 200, allowing a second end 108 of the structural member 106 to pivot upward away from the deck 115. This can be achieved, for example, by the hook-type connection illustrated in FIGS. 4A-5B and 7A-7B, via a pin connection that allows rotational freedom, among others. This is an advantage over conventional systems in that even after installation, the surface of the roof beneath the solar panel can easily be accessed. Because the solar panels are capable of pivoting, in some embodiments, a second end 108 of the structural member 106 may be coupled to the deck 115 of the roof 101, to prevent pivoting. In some embodiments, the second end 108 is detachably coupled to the deck 115, thus providing added stability while still allowing access beneath the panel 105. In some embodiments, the self weight of the panels 105 can prevent pivoting under design load cases.

It is to be understood that the embodiments and claims disclosed herein are not limited in their application to the details of construction and arrangement of the components set forth in the description and illustrated in the drawings. Rather, the description and the drawings provide examples of the embodiments envisioned. The embodiments and claims disclosed herein are further capable of other embodiments and of being practiced and carried out in various ways. Also, it is to be understood that the phraseology and terminology employed herein are for the purposes of description and should not be regarded as limiting the claims.

Accordingly, those skilled in the art will appreciate that the conception upon which the application and claims are based may be readily utilized as a basis for the design of other structures, methods, and systems for carrying out the several purposes of the embodiments and claims presented in this application. It is important, therefore, that the claims be regarded as including such equivalent constructions.

Furthermore, the purpose of the foregoing Abstract is to enable the United States Patent and Trademark Office and the public generally, and especially including the practitioners in the art who are not familiar with patent and legal terms or phraseology, to determine quickly from a cursory inspection the nature and essence of the technical disclosure of the application. The Abstract is neither intended to define the claims of the application, nor is it intended to be limiting to the scope of the claims in any way. Instead, it is intended that the invention is defined by the claims appended hereto.

What is claimed is:

1. A solar panel roof-ridge mounting system for use in mounting one or more solar panels to a roof of a building, the system comprising:
a base plate configured to interface with a deck of the roof at a roof-ridge, the base plate comprising a first side and an opposing second side, the first side configured for placement adjacent a first side of the roof-ridge and the second side configured for placement adjacent an opposing second side of the roof-ridge;
a plurality of attachment members coupled to the base plate, the attachment members configured to couple the roof-ridge mounting system to a support system of the one or more solar panels; and
a plurality of apertures in the base plate, the plurality of apertures for receiving a fastener for attaching the base plate to the deck of the roof.

2. The solar panel roof-ridge mounting system of claim 1, wherein each attachment member in the plurality of attachment members comprises a first end, a second end and at least one aperture between the first end and the second end.

3. The solar panel roof-ridge mounting system of claim 2, further comprising a connection member passing through the at least one aperture of at least two of the plurality of attachment members.

4. The solar panel roof-ridge mounting system of claim 3, wherein the connection member is arranged substantially parallel to at least one of the first side and the second side of the base plate.

5. The solar panel roof-ridge mounting system of claim 1, wherein at least a portion of the base plate between the first side and the second side is flexible to accommodate various pitch angles of the roof-ridge.

6. The solar panel roof-ridge mounting system of claim 1, wherein the baseplate comprises an alignment guide for aligning the base plate, the alignment guide comprising a first alignment point on a first end of the base plate and a second alignment point on a second end of the base plate, wherein the first and second alignment points are positioned on the base plate such that when the first and second alignment points are positioned proximate the roof-ridge, the first side of the base plate is substantially parallel to the roof-ridge.

7. The solar panel roof-ridge mounting system of claim 1, wherein the base plate further comprises a plurality of ventilation apertures for providing fluid communication between a space beneath the deck and an ambient atmosphere above the deck.

8. The solar panel roof-ridge mounting system of claim 1, further comprising a cap comprised of a hydrophobic material, the cap positioned substantially above the base plate to substantially prevent rain water from entering the plurality of apertures in the base plate.

9. A method of attaching one or more solar panels to a roof, the method comprising
placing a roof-ridge mounting system along a roof-ridge of the roof, such that a first side of the roof-ridge mounting system is positioned substantially on a first side of the roof-ridge and an opposing second side of the roof-ridge mounting system is positioned substantially on an second side of the roof-ridge;
attaching the roof-ridge mounting system to a deck of the roof;
coupling the one or more solar panels to a structural member of a solar panel support system; and
attaching a first end of the structural member to the roof-ridge mounting system proximate the first side of the roof-ridge mounting system.

10. The method of claim 9, wherein placing the roof-ridge mounting system along the roof-ridge comprises bending at least a portion of the roof-ridge mounting system between the first and second sides of the roof-ridge mounting system such that the first and second sides form an angle substantially equal to an angle formed by the first and second sides of the roof-ridge.

11. The method of claim 9, wherein attaching the roof-ridge mounting system to the deck comprises inserting one or more fasteners into the deck through one or more apertures in a base plate of the roof-ridge mounting system.

12. The method of claim 9, wherein the roof-ridge mounting system comprises a plurality of attachment members positioned along the first side of the roof-ridge mounting system, each attachment member in the plurality of attachment members comprising an aperture, wherein attaching a first end of the structural member to the roof-ridge mounting system comprises:
inserting a connection member through the apertures in the plurality of attachment members; and
placing a hook on the first end of the structural member around at least a portion of the connection member.

13. The method of claim 9, wherein the roof-ridge mounting system comprises a plurality of attachment members positioned along the first side of the roof-ridge mounting system, each attachment member in the plurality of attachment members comprising an aperture, wherein attaching a first end of the structural member to the roof-ridge mounting system comprises:
aligning a plurality of apertures on the first end of the structural member with the apertures on the plurality of attachment members; and
inserting a connection member through both the apertures on the first end of the structural member and the apertures on the plurality of attachment members.

14. The method of claim 9, further comprising attaching a hydrophobic cap over the roof-ridge mounting system, the cap substantially covering all penetrations in the deck of the roof used to attach the roof-ridge mounting system to the deck.

15. The method of claim 9, further comprising coupling a harness of a user to the roof-ridge mounting system.

16. The method of claim 9, further comprising:
attaching a hoist to the roof-ridge mounting system; and
hoisting the one or more solar panels with the hoist from a first location to a location proximate the roof-ridge mounting system.

17. The method of claim 9, wherein placing the roof-ridge mounting system along the roof-ridge comprises:
aligning a first alignment point on a base plate of the roof-ridge mounting system with roof-ridge; and
aligning a second alignment point on the base plate with the roof-ridge,
wherein after aligning the first and second alignment points, the first side of the roof-ridge mounting system is substantially parallel to the roof-ridge.

18. The method of claim 9, wherein the one or more solar panels is attached to the roof without any penetrations to the deck of the roof beneath the one or more solar panels.

19. The method of claim 9, further comprising attaching a second end of the structural member to the roof deck.

20. A solar panel roof-ridge mounting system for use in mounting one or more solar panels to a roof of a building, the system comprising:
a base plate configured to interface with a deck of the roof at a roof-ridge, the base plate comprising a first side and an opposing second side, the first side configured for placement adjacent a first side of the roof-ridge and the second side configured for placement adjacent an opposing second side of the roof-ridge;
a plurality of attachment members coupled to the base plate, the attachment members configured to couple the roof-ridge mounting system to a support system of the one or more solar panels, each attachment member in the plurality of attachment members comprising a first end, a second end and at least one aperture between the first end and the second end;
a plurality of apertures in the base plate, the plurality of apertures for receiving a fastener for attaching the base plate to the deck of the roof; and
a connection member passing through the at least one aperture of at least two of the plurality of attachment members, the connection member arranged substantially parallel to at least one of the first side and the second side of the base plate.
